(19) United States
(12) Patent Application Publication
(10) Pub. No.: US 2008/0050522 A1
(43) Pub. Date: Feb. 28, 2008

(54) Preparative method for protective layer of susceptor

(75) Inventors: Tsun-Neng Yang, Taipei City (TW); Shan-Ming Lan, Dasi Township (TW); Ying-Ru Chen, Dalin Township (TW); Chin-Chen Chiang, Dasi Township (TW); Hung-Sheng Chiu, Jhongli City (TW)

Correspondence Address: TROXELL LAW OFFICE PLLC, SUITE 1404, 5205 LEESBURG PIKE, FALLS CHURCH, VA, 22041, US

(73) Assignee: ATOMIC ENERGY COUNCIL-INSTITUTE OF NUCLEAR ENERGY RESEARCH, TAOYUAN (TW)

(21) Appl. No.: 11/508,235

(22) Filed: Aug. 23, 2006

(51) Int. Cl. C23C 16/00

(52) U.S. Cl. 427/249.1; 427/249.15; 427/249.19; 427/255.28; 427/255.7; 427/255.394; 427/255.395

(57) ABSTRACT

A protective layer for a susceptor is prepared. The susceptor is a graphite block; and the protective layer consists of a titanium nitride film and a titanium carbide film. The susceptor with the protective layer is used in epitaxial growth and device process with life time prolonged, energy saved, and cost reduced.

### FIELD OF THE INVENTION

The present invention relates to preparing a protective layer; more particularly, relates to preparing a protective layer of a graphite block, which comprises a titanium nitride film and a titanium carbide film.

### DESCRIPTION OF THE RELATED ARTS

A first prior art is U.S. Pat. No. 5,792,257, “Method for protecting the susceptor during epitaxial growth by CVD and a device for epitaxial growth by CVD,” where a protective layer having a susceptor made of SiC and a group III-nitride is deposited on a substrate by a chemical vapor deposition.

A second prior art of US patent is U.S. Pat. No. 6,183,553, “Process and apparatus for preparation of silicon crystals with reduced metal content”. A first preferred embodiment of the second prior art is a graphite having two protective layers, where a first protective layer is directly covered on the graphite; and a second protective layer is made of silicon and is covered on the first protective layer. A second preferred embodiment has only one protective layer directly covered on the graphite, made of a mixture of silicon carbide and silicon.

Although the above prior arts have protective layers for graphite susceptor made of silicon carbide and silicon, conductivity of silicon is bad. Hence, the prior arts do not fulfill users' requests on actual use.

### SUMMARY OF THE INVENTION

The main purpose of the present invention is to prepare a protective layer of a graphite block, comprising a titanium nitride film and a titanium carbide film, where a life time of the graphite block is prolonged; energy consumed is saved owing to the low heat conduction and high conductivity resistance; and production cost is greatly reduced.

To achieve the above purpose, the present invention is a preparative method for a protective layer of a susceptor, comprising steps of: processing a cutting and a polishing to a graphite block, then cleaning the graphite block with an alcohol solvent through supersonic waves, and hot-drying the graphite block after the cleaning; processing a thermal corrosion process to the graphite block to remove metal impurities; and, through chemical vapor depositions, depositing a titanium nitride film and a titanium carbide film sequentially with a first inter-layer formed between the graphite block and the titanium nitride film as well as a second inter-layer formed between the titanium nitride film and the titanium carbide film respectively. Accordingly, a novel preparative method for a protective layer of a susceptor is obtained.

### BRIEF DESCRIPTIONS OF THE DRAWINGS

The present invention will be better understood from the following detailed descriptions of the preferred embodiments according to the present invention, taken in conjunction with the accompanying drawings, in which

FIG. 1 is the view showing the flow chart according to the present invention;

FIG. 2A is the cross-sectional view showing the product obtained in step (c); and

FIG. 2B is the cross-sectional view showing the product obtained in step (d).

### DESCRIPTION OF THE PREFERRED EMBODIMENT

The following description of the preferred embodiment is provided to understand the features and the structures of the present invention.

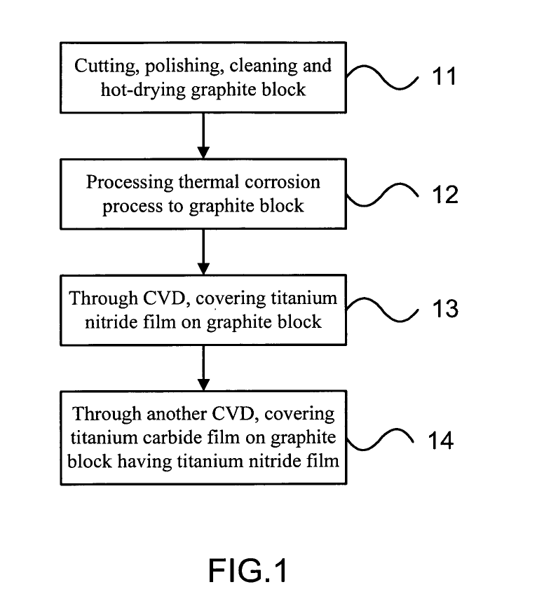

Please refer to FIG. 1, which is a view showing a flow chart according to the present invention. As shown in the figure, the present invention is a preparative method for a protective layer of a susceptor, where the susceptor is a graphite block and the protective layer comprises a titanium nitride film and a titanium carbide film. The preparative method comprises the following steps:

(a) Cutting, polishing, cleaning and hot-drying the graphite block 11: The graphite block is cut and is polished. Then the graphite block is cleaned with an alcohol solvent through supersonic waves. At last, the graphite block is hot-dried after the cleaning.

(b) Processing a thermal corrosion process to the graphite block 12: The graphite block is put into a radio-frequency (RF) furnace for a thermal corrosion process, where the thermal corrosion process uses hydrogen chloride and hydrogen gas and the hydrogen gas is a transport gas; the thermal corrosion process is processed under a temperature between 1100 Celsius degrees (° C.) and 1200° C.; and the thermal corrosion process removes metal impurities in the graphite block.

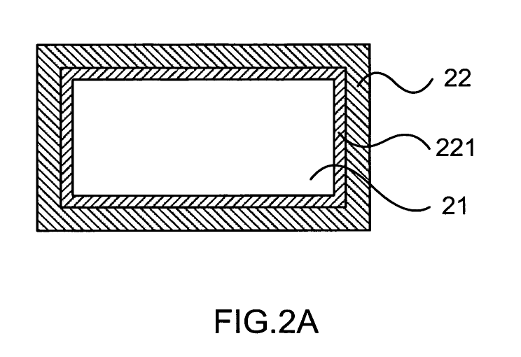

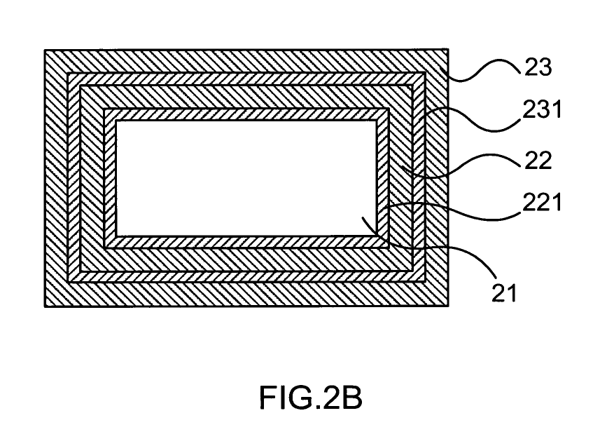

(c) Through a CVD, covering the titanium nitride film on the graphite block 13: Please further refer to FIG. 2A, which is a cross-sectional view showing a product obtained in step (c). As shown in the figure, through a chemical vapor deposition (CVD), the graphite block 21 obtained through step (b) is covered with the titanium nitride film 22 on a surface, where the CVD is an atmospheric pressure CVD or a low pressure CVD; precursors in the CVD are titanium tetrachloride and ammonia and the ammonia is a transport gas; the CVD is done under a temperature between 700° C. and 1200° C.; and the titanium nitride film 22 deposited on the graphite block 21 has a thickness between 1 micro meter (μm) and 5 μm. For the deposition is processed under a high temperature, atoms in the titanium nitride film 22 spread out to obtain a first inter-layer 221 between the graphite block 21 and the titanium nitride film 22, where the first inter-layer 221 is made of TiCₓN₁₋ₓ.

(d) Through another CVD, covering the titanium carbide film on the graphite block having the titanium nitride film 14: Please further refer to FIG. 2B, which is a cross-sectional view showing a product obtained in step (d). As shown in the figure, another CVD is processed to deposit a titanium carbide film 23 being covered on a surface of the graphite block 21 having the titanium nitride film 22, where precursors for the CVD are titanium tetrachloride and carbon tetra bromide and the transport gas is hydrogen gas; the CVD is processed under a temperature between 700° C. and 1200° C.; and the titanium carbide film 23 deposited on the surface of the graphite block 21 having the titanium nitride film 22 has a thickness between 1 μm and 25 μm. For the deposition is processed under a high temperature, a second inter-layer 231 is obtained between the titanium nitride film 22 and the titanium carbide film 23, where the first inter-layer 221 is made of TiCₓN₁₋ₓ. And the titanium nitride film 22 is a buffer layer between the graphite block 21 and the titanium carbide film 23.

Thus, a novel preparative method for a protective layer of a susceptor is obtained.

To sum up, the present invention is a preparative method for a protective layer of a susceptor, where a protective layer of a susceptor is prepared. The susceptor is a graphite block having the protective layer of a titanium nitride film and a titanium carbide film to obtain high conductivity, high chemical stability, high hardness, high abrasion sustainability and high fusion point. The present invention can be applied in an epitaxial growth and a device process while avoiding mechanical abrasion, where a lifetime of the graphite block is prolonged; energy consumed is saved owing to the low heat conduction and conductivity resistance; and production cost is greatly reduced.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. A preparative method for a protective layer of a susceptor, said susceptor being a graphite block, said protective layer comprising a titanium nitride film and a titanium carbide film, said preparative method comprising steps of:
(a) cutting and polishing said graphite block, then cleaning said graphite block with an alcohol solvent through supersonic waves, and hot-drying said graphite block after said cleaning;
(b) processing a thermal corrosion process to said graphite block in a radio-frequency furnace;
(c) through a chemical vapor deposition (CVD), depositing a titanium nitride film covered on a surface of said graphite block; and,
(d) through another CVD, depositing a titanium carbide film covered on a surface of said graphite block having said titanium nitride film.

2. The method according to claim 1,
wherein, in step (b), said thermal corrosion process has a temperature between 1100 Celsius degrees (° C.) and 1200° C.

3. The method according to claim 1,
wherein, in step (b), said thermal corrosion process uses hydrogen chloride and hydrogen gas; and
wherein said hydrogen gas is a transport gas.

4. The method according to claim 1,
wherein, in step (c), said CVD has a temperature between 700° C. and 1200° C.

5. The method according to claim 1,
wherein, in step (c), said titanium nitride film has a thickness between 1 micro meter (μm) and 25 μm.

6. The method according to claim 1,
wherein, in step (c), precursors in said CVD are titanium tetrachloride and ammonia.

7. The method according to claim 1,
wherein, in step (c), a transport gas in sa id CVD is hydrogen gas.

8. The method according to claim 1,
wherein, in step (c), a first inter-layer is obtained between said graphite block and said titanium nitride film.

9. The method according to claim 1,
wherein, in step (c), said CVD is selected from a group consisting of an atmospheric pressure CVD and a low pressure CVD.

10. The method according to claim 1,
wherein, in step (d), precursors in said another CVD are titanium tetrachloride and carbon tetrabromide.

11. The method according to claim 1,
wherein, in step (d), a transport gas in said another CVD is hydrogen gas.

12. The method according to claim 1,
wherein, in step (d), said titanium carbide film has a thickness between 1 μm and 25 μm.

13. The method according to claim 1,
wherein, in step (d), a second inter-layer is obtained between said titanium carbide film and said titanium nitride film.

14. The method according to claim 1,
wherein, in step (d), said another CVD is selected from a group consisting of an atmospheric pressure CVD and a low pressure CVD.
